(19) United States
(12) Patent Application Publication
(10) Pub. No.: US 2014/0119106 A1
(43) Pub. Date: May 1, 2014

(54) MAGNETIC MEMORY DEVICES AND METHODS OF OPERATING THE SAME

(71) Applicant: Samsung Electronics Co., Ltd., Suwon-si (KR)

(72) Inventors: Sung-chul LEE, Osan-si (KR); Kwang-seok KIM, Seongnam-si (KR); Kee-won KIM, Suwon-si (KR); Young-man JANG, Hwaseong-si (KR); Ung-hwan PI, Seoul (KR)

(21) Appl. No.: 13/938,573

(22) Filed: Jul. 10, 2013

(30) Foreign Application Priority Data
Oct. 25, 2012 (KR) 10-2012-0119295

(51) Int. Cl. H01L 43/02; G11C 11/16

(52) U.S. Cl. CPC H01L 43/02; G11C 11/1675
USPC 365/158; 257/421

(57) ABSTRACT

Magnetic memory devices, and methods of operating the same, include a magnetoresistive element, a current apply element for applying a spin transfer torque switching current to the magnetoresistive element, and a magnetic field apply element for applying a non-perpendicular magnetic field to the magnetoresistive element. The magnetic memory device writes data in the magnetoresistive element by using the spin transfer torque switching current and the non-perpendicular magnetic field. The magnetoresistive element includes a free layer and a pinned layer each having a perpendicular magnetic anisotropy.

### CROSS-REFERENCE TO RELATED APPLICATIONS

This application claims the benefit of priority under 35 U.S.C. §119 from Korean Patent Application No. 10-2012-0119295, filed on Oct. 25, 2012, in the Korean Intellectual Property Office, the disclosure of which is incorporated herein by reference in its entirety.

### BACKGROUND

1. Field

Example embodiments relate to magnetic memory devices and methods of operating the same.

2. Description of the Related Art

Magnetic random access memories (MRAMs) are memory devices that store data by using resistance variation of a magnetoresistive element such as a magnetic tunneling junction (MTJ) element. Resistance of the MTJ element varies according to the magnetization direction of a free layer. In other words, when the magnetization direction of a free layer is identical to that of a pinned layer, the MTJ element has a low resistance. When the magnetization direction of the free layer is opposite to that of the pinned layer, the MTJ element has a high resistance. If the MTJ element has a low resistance, data may correspond to ‘0’. On the other hand, if the MTJ element has a high resistance, data may correspond to ‘1’. MRAMs are drawing attention as one of the next-generation non-volatile memory devices due to characteristics including, for example, non-volatility, high-speed operation, and high endurance.

Recently, a spin transfer torque magnetic random access memory (STT-MRAM) that has an advantage of recording density improvement is drawing attention, and has been actively studied. However, in the case of the STT-MRAM, it is not easy to reduce the intensity of a writing current (that is, switching current) while ensuring a data retention characteristic (that is, thermal stability of data). Also, it is not easy to increase a magnetoresistance ratio (MR ratio) of an MTJ element while reducing the intensity of the writing current (that is, switching current). Accordingly, it is difficult to realize an STT-MRAM that satisfies all of writing easiness, data retention characteristic, and high MR ratio by using a conventional method.

### SUMMARY

Example embodiments relate to magnetic memory devices and methods of operating the same.

Provided are magnetic memory devices having high performance.

Provided are magnetic memory devices having high integration (high density) and high performance.

Provided are magnetic memory devices having an easiness in writing, high data retention characteristic, and high MR ratio.

Provided are magnetic memory devices that may reduce the intensity of writing current and reduce writing time.

Provided are magnetic memory devices that may record data by using a magnetic field (in-plane magnetic field) and a spin transfer torque.

According to example embodiments, a magnetic memory device includes a magnetoresistive element including a free layer and a pinned layer, wherein the free layer and the pinned layer each have a perpendicular magnetic anisotropy, a current apply element configured to apply a spin transfer torque switching current to the magnetoresistive element, and a magnetic field apply element configured to apply a non-perpendicular magnetic field to the magnetoresistive element, wherein the magnetic memory device is configured to write data in the magnetoresistive element by using the spin transfer torque switching current and the non-perpendicular magnetic field.

The non-perpendicular magnetic field may include an in-plane magnetic field.

The magnetic field apply element may include at least one conductive line spaced apart from the magnetoresistive element.

The conductive line may be above the magnetoresistive element. In this case, the magnetoresistive element may have a bottom-pinned structure in which the pinned layer is below the free layer.

The conductive line may be below the magnetoresistive element. In this case, the magnetoresistive element may have a top-pinned structure in which the pinned layer is above the free layer.

The magnetic field apply element may further include a driving device connected to the conductive line.

The driving device may include a transistor or a diode.

The current apply element may include a switching device and a bit line, the switching device may be connected to a first region of the magnetoresistive element and include a word line, and the bit line may be connected to a second region of the magnetoresistive element.

The magnetic field apply element may include a first conductive line above the bit line.

The first conductive line may extend in a direction parallel to the word line.

The first conductive line may extend in a direction perpendicular to the word line.

The magnetic field apply element may include a second conductive line below the magnetoresistive element, and the magnetoresistive element may be between the bit line and the second conductive line.

The second conductive line may extend in a direction parallel to the word line.

The word line may be the magnetic field apply element. In this case, the magnetoresistive element may be above the word line. The magnetoresistive element and the word line may be provided on the same vertical line.

The magnetic field apply element may include a first conductive line above the magnetoresistive element and a second conductive line below the magnetoresistive element. In this case, the first and second conductive lines may be parallel or perpendicular to each other.

The magnetic memory device may further include a magnetic field focusing member configured to focus the non-perpendicular magnetic field towards the magnetoresistive element.

The magnetic field focusing member may include a cladding layer surrounding a portion of the magnetic field apply element (for example, a conductive line), and the cladding layer may include an opening region facing the magnetoresistive element.

The memory device may include a plurality of magnetoresistive elements collectively arranged in a plurality of rows.

The magnetic field apply element may include at least one conductive line, and the conductive line may have a width that covers a first group from among the plurality of magnetoresistive elements, the first group being collectively arranged in at least two rows from among the plurality of rows.

The conductive line may be above the plurality of magnetoresistive elements.

The conductive line may be below the plurality of magnetoresistive elements.

The plurality of magnetoresistive elements may each include a first magnetoresistive element and a second magnetoresistive element, the current apply element may include a first switching device and a second switching device respectively connected to the first and second magnetoresistive elements. In this case, the first and second magnetoresistive elements may be between the first switching device and the second switching device. The conductive line may be below the first and second magnetoresistive elements and have a width that covers the first and second magnetoresistive elements.

The magnetic field apply element may be configured to start applying the non-perpendicular magnetic field to the magnetoresistive element before or simultaneously with the application of the spin transfer torque switching current to the magnetoresistive element.

According to example embodiments, there is provided a method of operating a magnetic memory device including a magnetoresistive element, the magnetoresistive element including a free layer and a pinned layer each having a perpendicular magnetic anisotropy, the method including writing data in a magnetoresistive element by applying a non-perpendicular magnetic field to the magnetoresistive element, and applying a spin transfer torque switching current to the magnetoresistive element while applying the non-perpendicular magnetic field to the magnetoresistive element.

The non-perpendicular magnetic field may include an in-plane magnetic field.

The applying of the non-perpendicular magnetic field to the magnetoresistive element is started before or simultaneously with the applying of the spin transfer torque switching current.

The applying of the non-perpendicular magnetic field is started in an amount of time ranging from about 0 ns to about 20 ns before the applying of the spin transfer torque switching current.

The magnetic memory device may further include at least one conductive line and the non-perpendicular magnetic field may be applied by using the conductive line.

The at least one conductive line may include a first conductive line above the magnetoresistive element. In this case, the magnetoresistive element may have a bottom-pinned structure in which the pinned layer is below the free layer.

The at least one conductive line may include a second conductive line below the magnetoresistive element. In this case, the magnetoresistive element may have a top-pinned structure in which the pinned layer is above the free layer.

The at least one conductive line may include the first conductive line above the magnetoresistive element and the second conductive line below the magnetoresistive element.

### BRIEF DESCRIPTION OF THE DRAWINGS

Example embodiments will be more clearly understood from the following detailed description taken in conjunction with the accompanying drawings. FIGS. 1-13 represent non-limiting, example embodiments as described herein.

FIGS. 1 through 4 are cross-sectional views of magnetic memory devices according to example embodiments;

FIGS. 5A through 5F are cross-sectional views for explaining a method of operating a magnetic memory device according to example embodiments;

FIG. 6 is a graph showing variations of amplitude according to time of a non-perpendicular magnetic field and a spin transfer torque switching current that may be used in a method of operating a magnetic memory device according to example embodiments;

FIGS. 7 through 10 are cross-sectional views of magnetic memory devices according to example embodiments;

FIG. 11 is a plan view of a magnetic memory device according to example embodiments;

FIG. 12 is a cross-sectional view of a magnetic memory device according to example embodiments; and

FIG. 13 is a graph showing a non-switching probability (Pns) with respect to switching current applying time in each switching conditions of magnetic memory devices according to example embodiments and a comparative example.

### DETAILED DESCRIPTION

Various example embodiments will now be described more fully with reference to the accompanying drawings in which example embodiments are shown.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In the drawings, the thicknesses of layers and regions may be exaggerated for clarity, and like numbers refer to like elements throughout the description of the figures.

Example embodiments relate to magnetic memory devices and methods of operating the same.

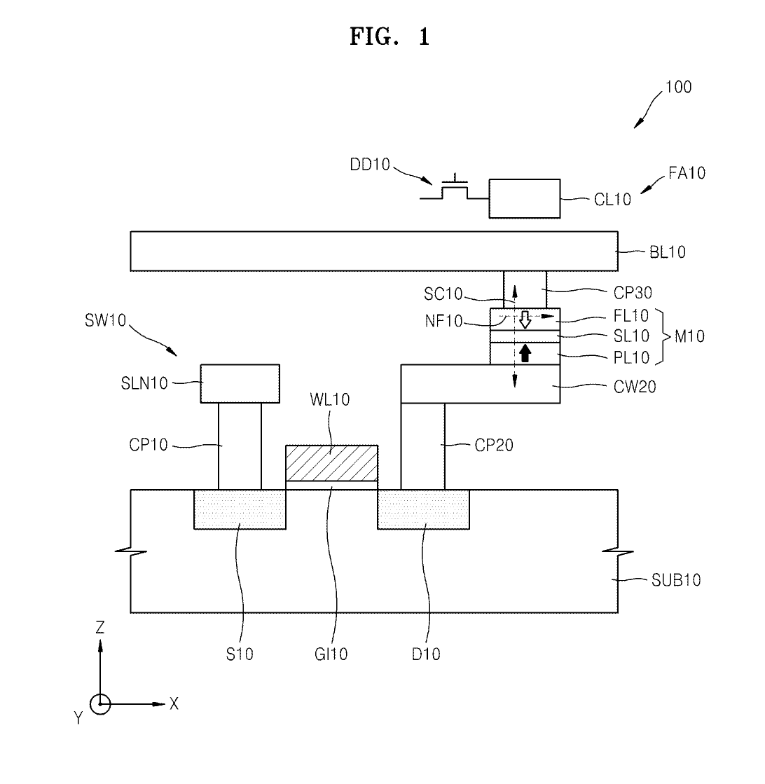

FIG. 1 is a cross-sectional view of a magnetic memory device according to example embodiments.

Referring to FIG. 1, a magnetic memory device 100 may include a magnetoresistive element M10. The magnetoresistive element M10 may include a free layer FL10 and a pinned layer PL10. The magnetoresistive element M10 may further include a separation layer SL10 between the free layer FL10 and the pinned layer PL10. The free layer FL10 is a magnetic layer that has a changeable magnetization direction and may be formed of a ferromagnetic material. The ferromagnetic material may include at least one selected from the group consisting of Co, Fe, and Ni, and also, may further include another element, for example, B, Cr, Pt, and Pd. The free layer FL10 may have a thickness in a range from about 1 nm to about 15 nm, for example, in a range from about 2 nm to about 10 nm. The pinned layer PL10 has a fixed magnetization direction and may be formed of a ferromagnetic material including at least one of Co, Fe, and Ni. The ferromagnetic material may further include another element, for example, B, Cr, Pt, and Pd besides Co, Fe, and Ni. The free layer FL10 and the pinned layer PL10 may be formed of the same material or materials different from each other. The pinned layer PL10 may have a thickness approximately 10 nm or less, for example, approximately 5 nm or less.

The free layer FL10 and the pinned layer PL10 each may have a perpendicular magnetic anisotropy. In this case, the free layer FL10 and/or the pinned layer PL10 may include a Co-based material, and may include a single-layered or a multi-layered structure. For example, the free layer FL10 and/or the pinned layer PL10 may include at least one selected from the group consisting of Co, CoFe, CoFeB, CoCr, and CoCrPt, or may have a [Co/Pd]ₙ structure, a [Co/Ni]ₙ structure, or a [Co/Pt]ₙ structure. In the [Co/Pd]ₙ structure, ‘n’ refers to the repeating number of the stack of Co and Pd, wherein Co and Pd are alternately stacked. In the [Co/Ni]ₙ and [Co/Pt]ₙ structures, ‘n’ has the same meaning as described above. The materials for forming the free layer FL10 and the pinned layer PL10 are merely examples, and, various other materials may also be used to form the free layer FL10 and the pinned layer PL10.

The separation layer SL10 may be formed of an insulating material. For example, the separation layer SL10 may include an insulating oxide, such as, a magnesium oxide and an aluminum oxide. When the separation layer SL10 is formed of an insulating material, the magnetoresistive element M10 may be a magnetic tunneling junction (MTJ) element. However, the material for the separation layer SL10 is not limited to these materials. In some cases, the separation layer SL10 may be formed of a conductive material. In this case, the separation layer SL10 may include at least one conductive material (metal) selected from the group consisting of Ru, Cu, Al, Au, Ag, and a mixture of these materials. The separation layer SL10 may have a thickness of approximately 5 nm or less, for example, approximately 3 nm or less.

In the current example embodiments, the separation layer SL10 and the free layer FL10 may be sequentially stacked on the pinned layer PL10. That is, in the current example embodiments, the magnetoresistive element M10 may have a bottom-pinned structure in which the pinned layer PL10 is disposed under the free layer FL10.

The magnetoresistive element M10 may have a width (or diameter) of several tens of nm or less, for example, approximately 20 nm or less or approximately 15 nm or less. When the free layer FL10 and the pinned layer PL10 have a perpendicular magnetic anisotropy, the width (or diameter) of the magnetoresistive element M10 may be readily reduced, and thus, the magnetoresistive element M10 according to the current example embodiments may be suitable for realizing a highly integrated (high density) magnetic memory device.

In FIG. 1, arrows (vertical arrows) depicted in the free layer FL10 and the pinned layer PL10 indicate magnetization directions that the free layer FL10 and the pinned layer PL10 may have. The magnetization direction of the pinned layer PL10 is fixed, and that of the free layer FL10 may be reversed. For example, the magnetization direction of the pinned layer PL10 may be fixed in a Z-axis direction. The magnetization direction of the free layer FL10 may be reversed between the Z-axis direction and a reverse Z-axis direction. Here, it is depicted that the free layer FL10 is magnetized in the reverse Z-axis direction. The directions (magnetization directions) of the arrows in FIG. 1 are example, and thus, may vary.

A switching device SW10 connected to the magnetoresistive element M10 may be provided. The switching device SW10 may be, for example, a transistor. In this case, the switching device SW10 may include a word line WL10 provided on a substrate SUB10 and a source region S10 and a drain region D10 provided on both sides of the word line WL10. The word line WL10 may extend in a Y-axis direction. The word line WL10 may be referred to as ‘a gate line’ or ‘a gate electrode’. A gate insulating layer GI10 may be provided between the word line WL10 and the substrate SUB10. A source line SLN10 connected to the source region 510 may be provided. The source region S10 and the source line SLN10 may be connected to each other via a first contact plug CP10. The source line SLN10 may extend in an X-axis direction or the Y-axis direction. The drain region D10 may be electrically connected to a first region (a first end portion) of the magnetoresistive element M10. For example, the drain region D10 may be connected to a lower surface of the magnetoresistive element M10. The drain region D10 may be connected to the magnetoresistive element M10 via a second contact plug CP20 and a connection wire CW20. The connection structure of the drain region D10 and the magnetoresistive element M10 may be varied in various forms. For example, without using the connection wire CW20, the magnetoresistive element M10 may be disposed on the second contact plug CP20. Also, in the switching device SW10, functions of the source region S10 and the drain region D10 may be switched.

A bit line BL10 connected to the magnetoresistive element M10 may be provided. The bit line BL10 may be electrically connected to a second region (a second end portion) of the magnetoresistive element M10. For example, the bit line BL10 may be connected to an upper surface of the magnetoresistive element M10. The bit line BL10 may be connected to the magnetoresistive element M10 via a third contact plug CP30. However, in some cases, without using the third contact plug CP30, the bit line BL10 may contact on the upper surface of the magnetoresistive element M10. The bit line BL10 may extend, for example, in a perpendicular direction to the word line WL10. That is, the bit line BL10 may extend in the X-axis direction. However, in some cases, the bit line BL10 may extend in a direction parallel to the word line WL10 (that is, the Y-axis direction).

A spin transfer torque switching current SC10 may be applied to the magnetoresistive element M10 through the switching device SW10 and the bit line BL10. If an element that applies the spin transfer torque switching current SC10 to the magnetoresistive element M10 is referred to as a “current apply element”, the current apply element may include the switching device SW10 and the bit line BL10. The spin transfer torque switching current SC10 will be described later in more detail.

A magnetic field apply element FA10 for applying a non-perpendicular magnetic field NF10 to the magnetoresistive element M10 may further be provided. The magnetic field apply element FA10 may include a conductive line CL10 provided above the bit line BL10. The conductive line CL10, for example, may extend in a direction (that is, the Y-axis direction) parallel to the word line WL10. Accordingly, the conductive line CL10 may extend in a direction perpendicular to the bit line BL10. When a selected current flows in the conductive line CL10, the non-perpendicular magnetic field NF10 may be generated from the conductive line CL10. The direction (that is, non-perpendicular direction) of the non-perpendicular magnetic field NF10 is regard to the magnetoresistive element M10, in particular, to the free layer FL10. The non-perpendicular magnetic field NF10 may be an in-plane magnetic field. That is, an in-plane magnetic field (i.e., the non-perpendicular magnetic field NF10) may be applied to the magnetoresistive element M10, particularly, to the free layer FL10. The non-perpendicular magnetic field NF10 may have intensity in a range from about 20 Oersted (Oe) to about 2000 Oe, for example, in a range from about 100 Oe to about 2000 Oe.

A driving device DD10 connected to the conductive line CL10 may be further provided. The driving device DD10 may include a transistor or a diode. Here, it is depicted that the driving device DD10 is a transistor. A selected current may be applied to the conductive line CL10 through the driving device DD10, and accordingly, the non-perpendicular magnetic field NF10 may be generated from the conductive line CL10. Although not shown, a selected current source connected to the driving device DD10 may further be provided. It may be referred that the magnetic field apply element FA10 includes the driving device DD10 and the current source.

In the current example embodiments, data may be recorded in the magnetoresistive element M10 by using the non-perpendicular magnetic field NF10 (for example, an in-plane magnetic field) and the spin transfer torque switching current SC10. In other words, the magnetization direction of the free layer FL10 may be reversed by using the non-perpendicular magnetic field NF10 and the spin transfer torque switching current SC10. The magnetization direction of the free layer FL10 may be reversed by applying the spin transfer torque switching current SC10 after fluctuating the magnetization direction of the free layer FL10 by applying the non-perpendicular magnetic field NF10 (for example, an in-plane magnetic field). In this regard, according to example embodiments, writing of data (that is, the magnetization reverse of the free layer FL10) may be easily performed. Also, the effect of the non-perpendicular magnetic field NF10 increases as the thickness of the free layer FL10 is increased. Thus, it is advantageous to improve in the thermal stability (that is, data retention characteristic) of the free layer FL10 and increase in the MR ratio of the magnetoresistive element M10. Therefore, according to the current example embodiments, a magnetic memory device in which data writing is easily performed, and that has a high data retention characteristic and high MR ratio may be realized. The effects of example embodiments will be described later in more detail.

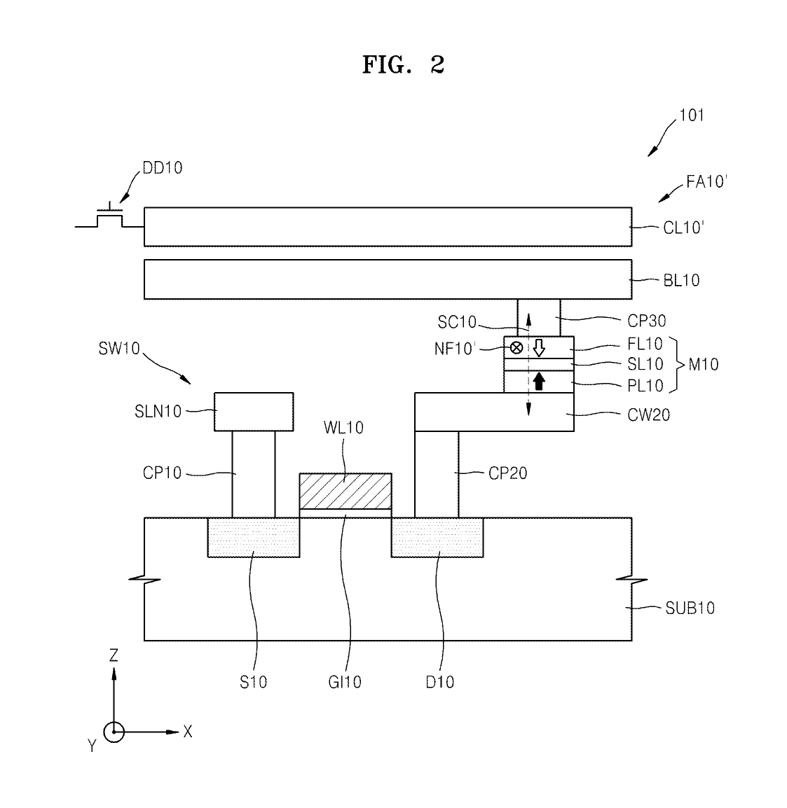

According to other example embodiments, the location and structure of the magnetic field apply element FA10 may be modified in various ways. For example, in FIG. 1, the extention direction of the conductive line CL10 may vary. An example is shown in FIG. 2. FIG. 2 is a cross-sectional view of a magnetic memory device according to other example embodiments.

Referring to FIG. 2, a conductive line CL10′ of a magnetic field apply element FA10′ may extend in the X-axis direction. That is, the conductive line CL10′ may extend in a direction parallel to the bit line BL10, in other words, in a direction perpendicular to the word line WL10. In this case, a non-perpendicular magnetic field NF10′ may be applied in a direction parallel to the Y-axis direction. The magnetization direction of the free layer FL10 may be fluctuated in the Y-axis direction by the non-perpendicular magnetic field NF10′. At this point, the magnetization direction of the free layer FL10 may be reversed by applying the spin transfer torque switching current SC10.

In FIGS. 1 and 2, because the magnetoresistive element M10 has a bottom-pinned structure, the free layer FL10 may be disposed closer to the conductive line CL10 and CL10′ than the pinned layer PL10. Therefore, the non-perpendicular magnetic field NF10 and NF10′ generated from the conductive line CL10 and CL10′ may be easily applied to the free layer FL10 than the pinned layer PL10. In other words, the non-perpendicular magnetic field NF10 and NF10′ may be applied to the free layer FL10 with intensity greater than that of the pinned layer PL10. In this regard, in the example embodiments of FIGS. 1 and 2, the magnetoresistive element M10 may have a bottom-pinned structure. However, in some cases, the magnetoresistive element M10 may have a top-pinned structure not the bottom-pinned structure.

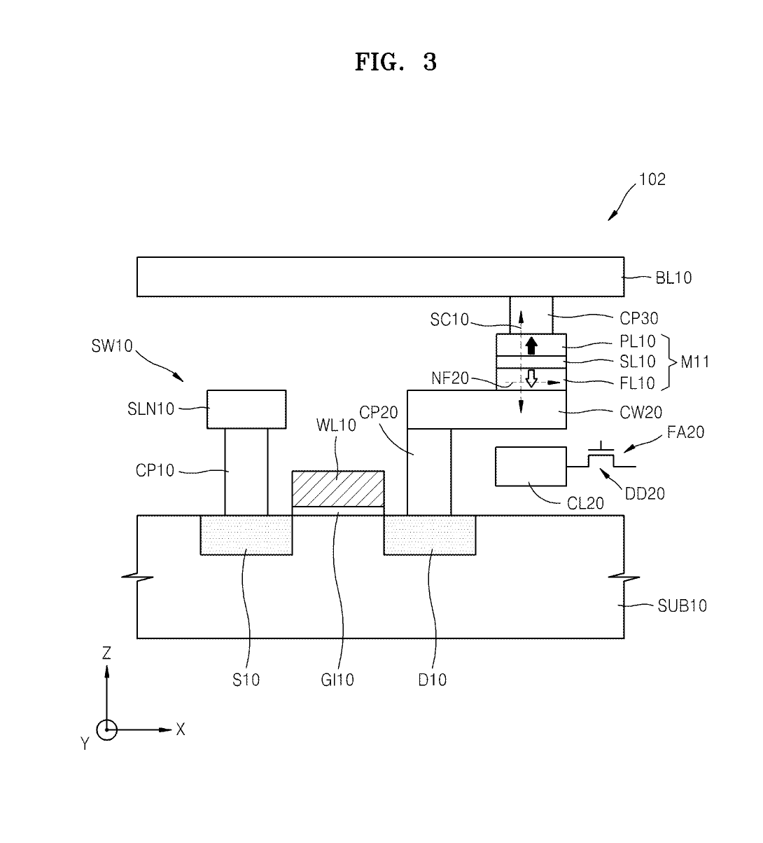

According to other example embodiments, the conductive line CL10 may be disposed below the magnetoresistive element M10. An example of the structure is illustrated in FIG. 3. FIG. 3 is a cross-sectional view of a magnetic memory device according to other example embodiments.

Referring to FIG. 3, a conductive line CL20 of a magnetic field apply element FA20 may be disposed below a magnetoresistive element M11. In this case, the conductive line CL20 mat extend in a direction parallel to the word line WL10, that is, in the Y-axis direction. A non-perpendicular magnetic field NF20 (for example, an in-plane magnetic field) may be applied to the magnetoresistive element M11 from the conductive line CL20. The magnetic field apply element FA20 may further include a driving device DD20 connected to the conductive line CL20. The driving device DD20 may be a transistor or a diode. Here, it is depicted that the driving device DD20 is a transistor.

In the current example embodiments, as depicted in FIG. 3, if the conductive line CL20 is disposed below the magnetoresistive element M11, the magnetoresistive element M11 may have a top-pinned structure in which the pinned layer PL10 is disposed above the free layer FL10. In this case, because the free layer FL10 is disposed closer to the conductive line CL20 than the pinned layer PL10, the non-perpendicular magnetic field NF20 generated from the conductive line CL20 may be easily applied to the free layer FL10 than the pinned layer PL10. However, in some cases, the magnetoresistive element M11 may have a bottom-pinned structure not the top-pinned structure.

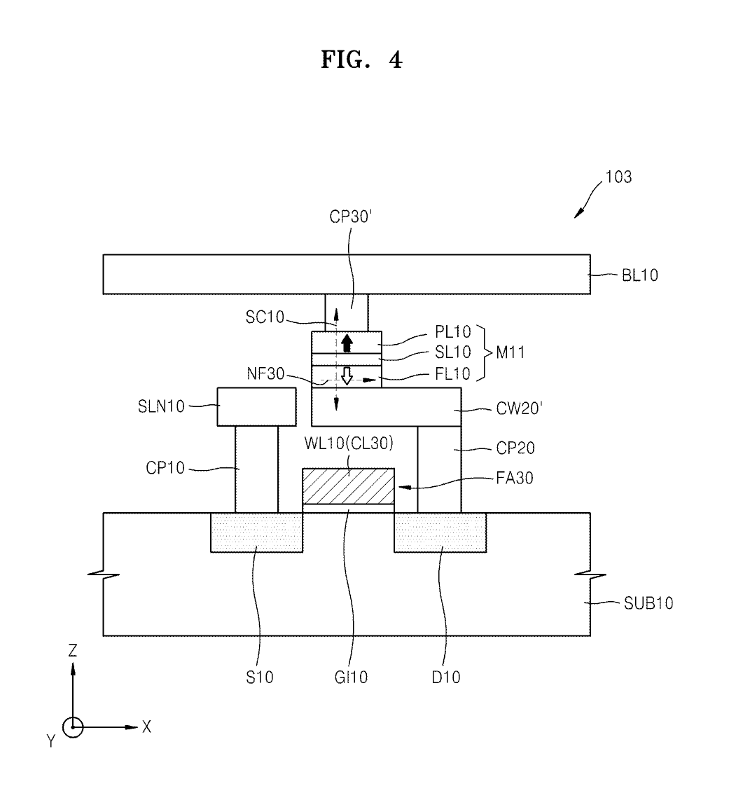

According to other example embodiments, the word line WL10 itself may be used as a conductive line for applying a magnetic field. An example thereof is illustrated in FIG. 4. FIG. 4 is a cross-sectional view of a magnetic memory device according to other example embodiments.

Referring to FIG. 4, the magnetoresistive element M11 may be disposed directly above the word line WL10. The word line WL10 and the magnetoresistive element M11 may be disposed on the same vertical line. In this case, a connection structure for connecting the drain region D10 to the magnetoresistive element M11 may be modified from the structure depicted in FIG. 1. That is, a connection wire CW20′ may extend above the word line WL10 from the second contact plug CP20, and the magnetoresistive element M11 may be disposed on an end portion of the connection wire CW20′. In this case, the word line WL10 may be used as a conductive line CL30 for applying a magnetic field. That is, the word line WL10 itself may be used as a magnetic field apply element FA30. In other words, a selected non-perpendicular magnetic field NF30 (for example, an in-plane magnetic field) may be applied to the magnetoresistive element M11 by using the word line WL10. The magnetoresistive element M11 may have a top-pinned structure in which the pinned layer PL10 is disposed above the free layer FL10. Also, in the current example embodiments, the magnetoresistive element M11 may be connected to the bit line BL10 via a third contact plug CP30′. In some cases, the bit line BL10 may contact on an upper surface of the magnetoresistive element M11 without using the third contact plug CP30′.

In the current example embodiments as depicted in FIG. 4, data may be recorded in the magnetoresistive element M11 by using the non-perpendicular magnetic field NF30 (for example, an in-plane magnetic field) and the spin transfer torque switching current SC10.

In the example embodiments as depicted in FIGS. 1 through 4, gaps between the conductive lines CL10, CL10′, CL20, and CL30 and the magnetoresistive elements M10 and M11 may be in a range from several tens of nm to several hundreds nm. The gaps between the conductive lines CL10, CL10′, CL20, and CL30 and the magnetoresistive elements M10 and M11 may be determined at approximately 500 nm or less. Also, the conductive lines CL10, CL10′, CL20, and CL30 may have a width similar to that of the magnetoresistive elements M10 and M11, but may have a width greater than that of the magnetoresistive elements M10 and M11. The larger the width of the conductive lines CL10, CL10′, CL20, and CL30, the larger the intensity of magnetic fields (that is, non-perpendicular magnetic field NF10, NF10′, NF20, and NF30) generated from the conductive lines CL10, CL10′, CL20, and CL30.

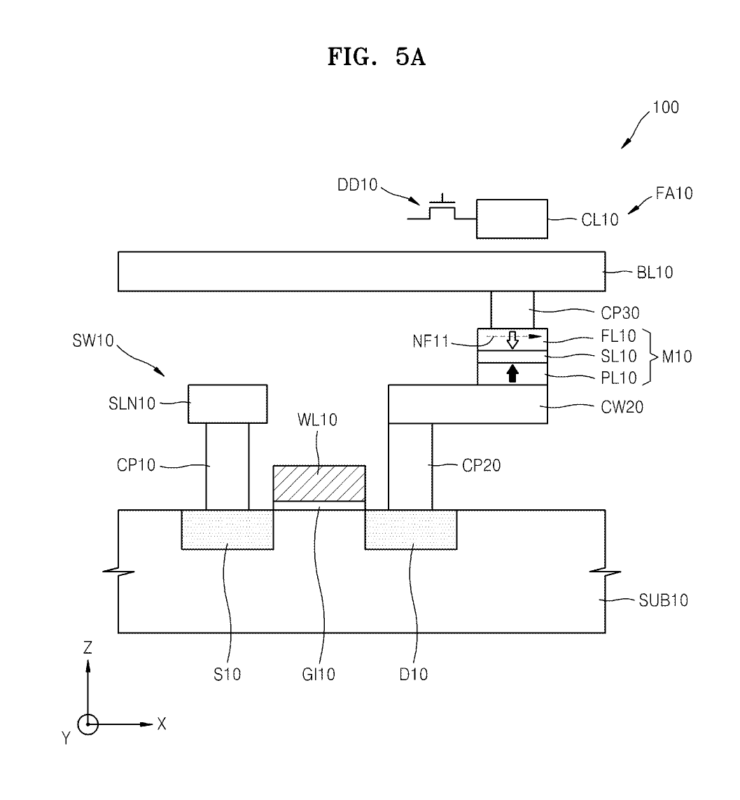

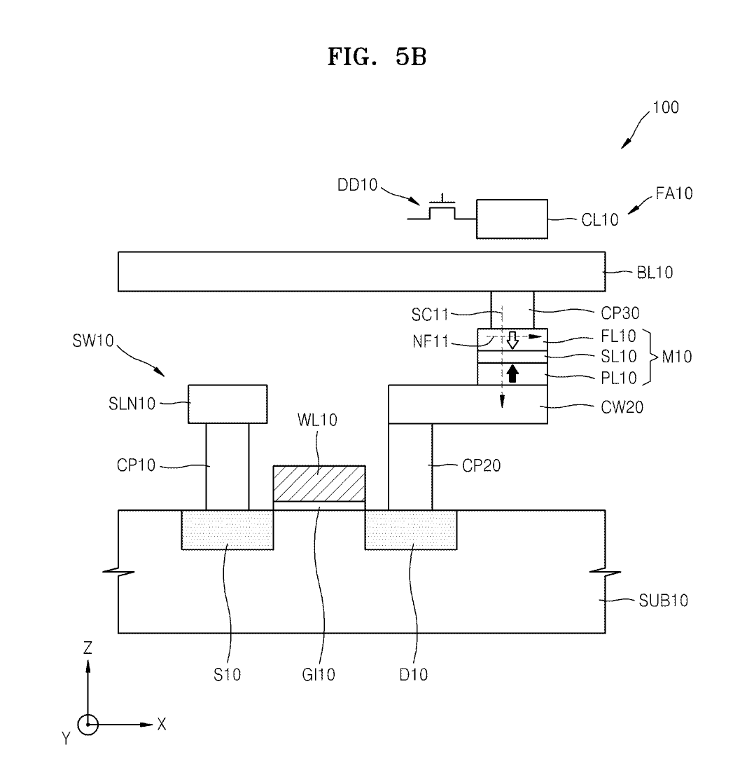

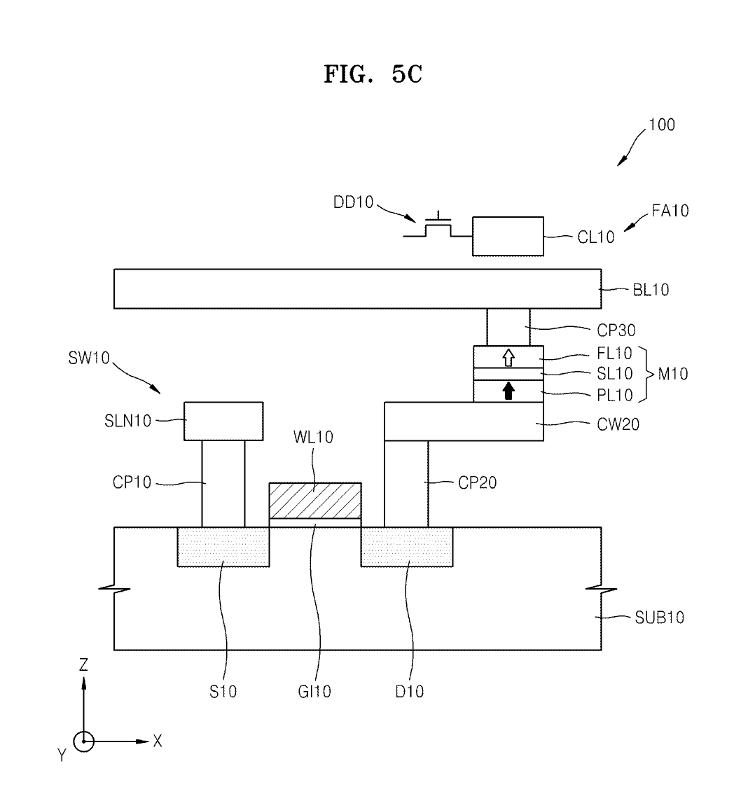

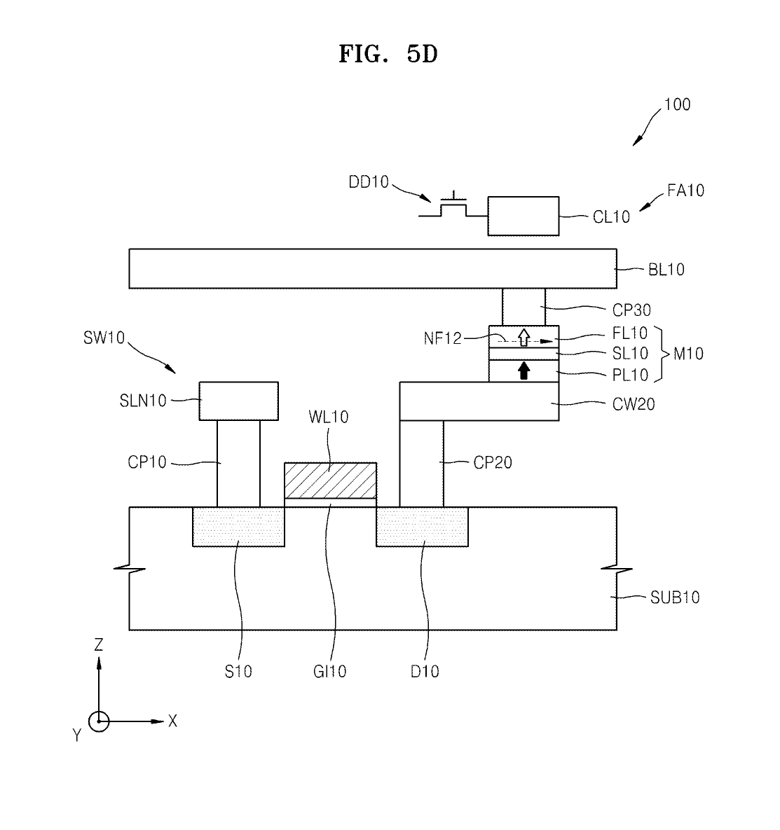

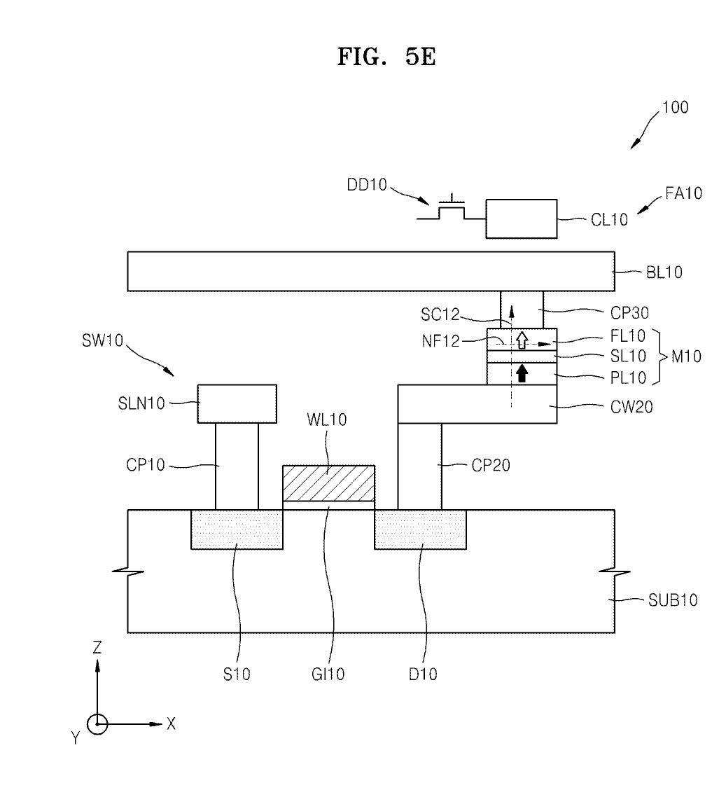

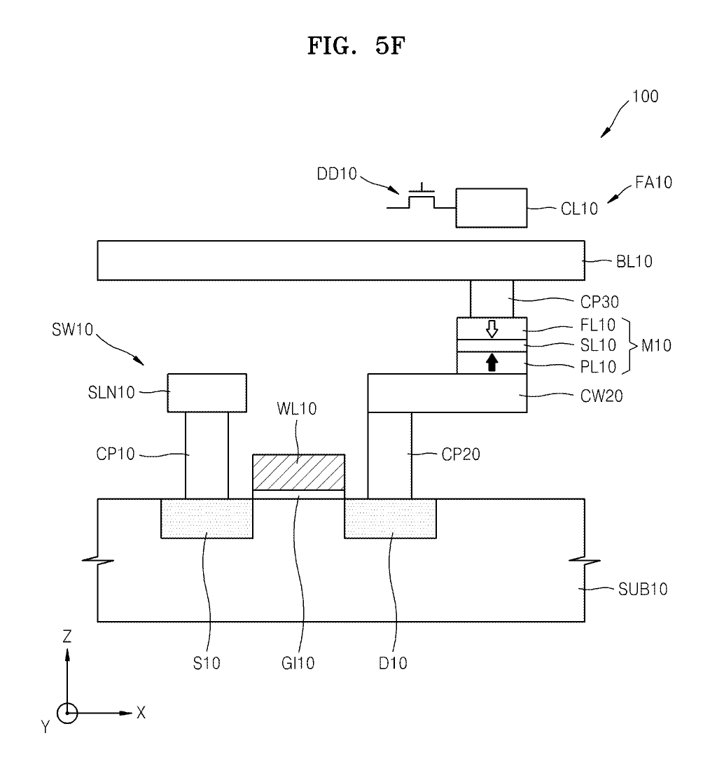

Hereinafter, a method of operating the magnetic memory device according to example embodiments will be described with reference to FIGS. 5A through 5F. The magnetic memory device is the magnetic memory device depicted in FIG. 1.

Referring to FIG. 5A, the pinned layer PL10 of the magnetoresistive element M10 may have a magnetization direction fixed in the Z-axis direction, and the free layer FL10 may be in a magnetized state in a reverse direction of the Z-axis direction. At this point, a first non-perpendicular magnetic field NF11 may be applied to the free layer FL10 from the conductive line CL10 by applying a selected current (not shown) to the conductive line CL10 of the magnetic field apply element FA10. The first non-perpendicular magnetic field NF11 may be, for example, an in-plane magnetic field. The magnetization (vertical magnetization) of the free layer FL10 may be fluctuated in a horizontal direction by the first non-perpendicular magnetic field NF11.

Referring to FIG. 5B, in a state that the first non-perpendicular magnetic field NF11 is applied to the free layer FL10, a first spin transfer torque switching current SC11 may be applied to the magnetoresistive element M10 through the switching device SW10 and the bit line BL10. The first spin transfer torque switching current SC11 may flow from the bit line BL10 to the switching device SW10. That is, in the magnetoresistive element M10, the first spin transfer torque switching current SC11 may flow in a direction opposite to the Z-axis direction. Accordingly, electrons (not shown) may flow from the switching device SW10 towards the bit line BL10 by the first spin transfer torque switching current SC11. That is, in the magnetoresistive element M10, the electrons may flow in the Z-axis direction. In other words, the electrons may flow from the pinned layer PL10 towards the free layer FL10. The electrons that flow from the pinned layer PL10 to the free layer FL10 may apply a spin torque to the free layer FL10 with a spin direction as the same as the pinned layer PL10. Therefore, the magnetization direction of the free layer FL10 may be reversed to have the same direction as the magnetization direction of the pinned layer PL10.

FIG. 5C shows a result of the magnetization reversal of the free layer FL10 of FIG. 5B. As such, the state in which the free layer FL10 is magnetized in the same direction as the pinned layer PL10 may be referred as a parallel state, and the magnetoresistive element M10 may have a low resistance (first resistance). In this case, it may be regarded as ‘a first data’ is recorded in the magnetoresistive element M10.

Referring to FIG. 5D, similar to the operation described with reference to FIG. 5A, a second non-perpendicular magnetic field NF12 may be applied to the free layer FL10 from the conductive line CL10. The second non-perpendicular magnetic field NF12 may be an in-plane magnetic field. The second non-perpendicular magnetic field NF12 may be substantially the same magnetic field as the first non-perpendicular magnetic field NF11 of FIG. 5A. The magnetization direction (vertical magnetization) of the free layer FL10 may be fluctuated in the horizontal direction by the second non-perpendicular magnetic field NF12.

Referring to FIG. 5E, in a state that the second non-perpendicular magnetic field NF12 is applied to the free layer FL10, a second spin transfer torque switching current SC12 may be applied to the magnetoresistive element M10 through the switching device SW10 and the bit line BL10. The second spin transfer torque switching current SC12 may flow from the switching device SW10 towards the bit line BL10. That is, in the magnetoresistive element M10, the second spin transfer torque switching current SC12 may flow in the Z-axis direction. Therefore, electrons (not shown) may flow from the bit line BL10 towards the switching device SW10 by the second spin transfer torque switching current SC12. That is, in the magnetoresistive element M10, the electrons may flow in a direction opposite to the Z-axis direction. In other words, the electrons may flow from the free layer FL10 towards the pinned layer PL10. The magnetization of the free layer FL10 may be reversed to be a direction opposite to that of the pinned layer PL10 by the electrons that flow from the free layer FL10 towards the pinned layer PL10. This is because, of the electrons that flow towards the pinned layer PL10, electrons having spin as the same as that of the pinned layer PL10 pass through the pinned layer PL10 towards the switching device SW10, but electrons having spin opposite to that of the pinned layer PL10 return to the free layer FL10 and apply spin torque to the free layer FL10. That is, since electrons having spin opposite to that of the pinned layer PL10 apply a spin torque to the free layer FL10, the magnetization of the free layer FL10 may be reversed to a direction opposite to that of the pinned layer PL10.

FIG. 5F shows a result of the magnetization reversal of the free layer FL10 of FIG. 5E. As such, the state in which the free layer FL10 is magnetized in a direction opposite to that of the pinned layer PL10 is referred to as an anti-parallel state and the magnetoresistive element M10 may have a high resistance (a second resistance). In this case, it may be regarded as ‘a second data’ is recorded in the magnetoresistive element M10.

According to the current example embodiments, after fluctuating the magnetization of the free layer FL10 in a non-perpendicular direction (for example, in a horizontal direction) by using the non-perpendicular magnetic fields NF11 and NF12 in the operations described with reference to FIGS. 5A and 5D, the magnetization of the free layer FL10 is reversed by using the spin transfer torque switching current SC11 and SC12 in the operations FIGS. 5B and 5E, and thus, the magnetization reverse of the free layer FL10 may be easily realized. The magnetic memory device 100 according to the current example embodiments may be referred to as a spin transfer torque magnetic random access memory (STT-MRAM) having a writing method assisted by a magnetic field. That is, the magnetic memory device 100 may be a magnetic field assisted STT-MRAM.

In the current example embodiments, the non-perpendicular magnetic fields NF11 and NF12 may be applied to the magnetoresistive element M10 before applying the spin transfer torque switching currents SC11 and SC12 corresponding thereto. That is, in a state that the non-perpendicular magnetic field NF11 or NF12 is applied to the magnetoresistive element M10 in advance, the spin transfer torque switching current SC11 or SC12 corresponding to the non-perpendicular magnetic field NF11 or NF12 may be applied to the magnetoresistive element M10. For example, the first non-perpendicular magnetic field NF11 may be applied to the magnetoresistive element M10 at a point within approximately 20 ns earlier than the application of the first spin transfer torque switching current SC11. Similarly, the second non-perpendicular magnetic field NF12 may be applied to the magnetoresistive element M10 at a point within approximately 20 ns earlier than the application of the second spin transfer torque switching current SC12. However, in some cases, the non-perpendicular magnetic field NF11 and NF12 and the spin transfer torque switching current SC11 and SC12 corresponding to the non-perpendicular magnetic field NF11 and NF12 may be simultaneously applied to the magnetoresistive element M10. The application time difference between the first non-perpendicular magnetic field NF11 and the first spin transfer torque switching current SC11 may be in a range from about 0 to about 20 ns. Similarly, the application time difference between the second non-perpendicular magnetic field NF12 and the second spin transfer torque switching current SC12 may also be in a range from about 0 to about 20 ns.

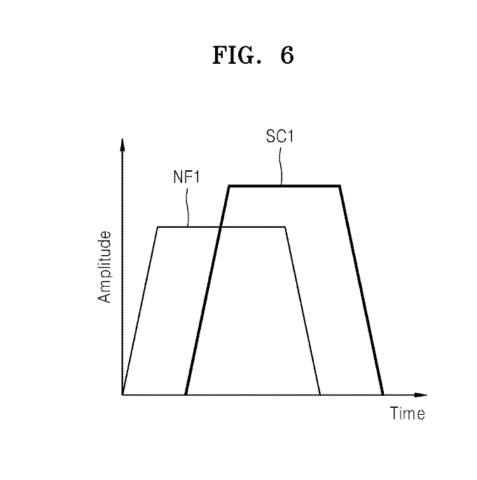

FIG. 6 is a graph showing a variation of amplitude according to time of a non-perpendicular magnetic field and a spin transfer torque switching current that may be used in a method of operating a magnetic memory device according to example embodiments.

FIG. 6 shows an example of the difference of applying point of a non-perpendicular magnetic field NF1 and a spin transfer torque switching current SC1 that are used for data recording. Here, the non-perpendicular magnetic field NF1 and the spin transfer torque switching current SC1 respectively may correspond to the first non-perpendicular magnetic field NF11 of FIG. 5A and the first spin transfer torque switching current SC11 of FIG. 5B.

Referring to FIG. 6, the non-perpendicular magnetic field NF1 may be applied earlier than the application of the spin transfer torque switching current SC1. For example, the difference of applying point between the non-perpendicular magnetic field NF1 and the spin transfer torque switching current SC1 may be in a range from about 0 ns to about 20 ns. At this point, the retention time (that is, a width of the graph) of the non-perpendicular magnetic field NF1 may be in a range from about 5 ns to about 50 ns, for example, in a range from about 10 ns to about 30 ns. The retention time of the spin transfer torque switching current SC1 may be in a range from about 5 ns to about 50 ns, for example, in a range from about 10 ns to about 30 ns. The variation of the amplitude according to the time of the non-perpendicular magnetic field NF1 and the spin transfer torque switching current SC1 shown in FIG. 6 is an example, and thus, may be changed in various ways.

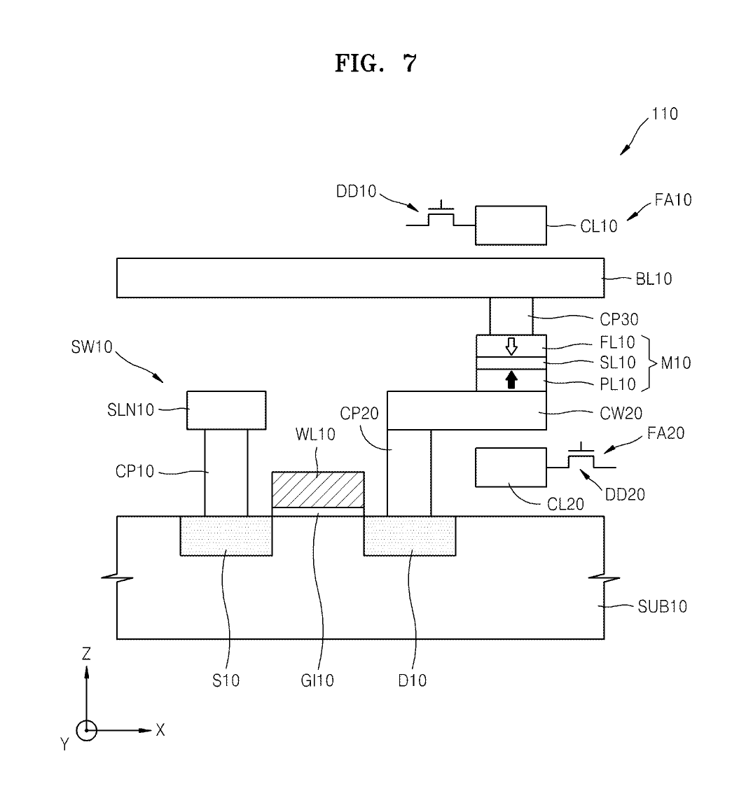

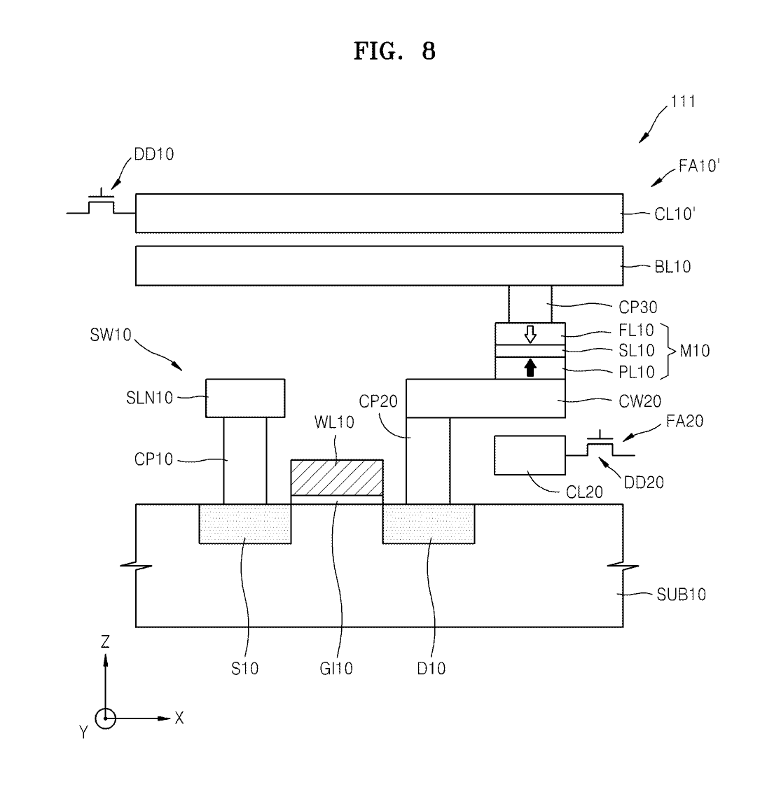

According to other example embodiments, among the magnetic field apply elements FA10, FA10′, FA20, and FA30 depicted in FIGS. 1 through 4, at least two of them may be used in combination. The examples are shown in FIGS. 7 and 8. That is, FIGS. 7 and 8 show magnetic memory devices according to other example embodiments.

Referring to FIG. 7, a first conductive line CL10 may be provided above the magnetoresistive element M10, and a second conductive line CL20 may be provided below the magnetoresistive element M10. The first conductive line CL10 may correspond to the conductive line CL10 of FIG. 1, and the second conductive line CL20 may correspond to the conductive line CL20 of FIG. 3. The first and second conductive lines CL10 and CL20 may be parallel to the word line WL10 and may be perpendicular to the bit line BL10. Here, the magnetoresistive element M10, as depicted in FIG. 7, may be a bottom-pinned structure in which the pinned layer PL10 is provided below the free layer FL10, or, may be a top-pinned structure in which the pinned layer PL10 is provided above the free layer FL10. The direction of a non-perpendicular magnetic field (not shown) applied to the free layer FL10 from the first conductive line CL10 and the direction of a non-perpendicular magnetic field (not shown) applied to the free layer FL10 from the second conductive line CL20 may be the same. In this way, when non-perpendicular magnetic fields (not shown) are applied to the free layer FL10 by using the two conductive lines CL10 and CL20, the intensity of the non-perpendicular magnetic field may be increased.

Referring to FIG. 8, a first conductive line CL10′ may be provided above the magnetoresistive element M10, and a second conductive line CL20 may be provided below the magnetoresistive element M10. The first conductive line CL10′ may correspond to the conductive line CL10′ of FIG. 2, and the second conductive line CL20 may correspond to the conductive line CL20 of FIG. 3. The first conductive line CL10′ may be perpendicular to the word line WL10, and the second conductive line CL20 may be parallel to the word line WL10. Here, the magnetoresistive element M10 may be a bottom-pinned structure, and also, may be a top-pinned structure. The direction of a non-perpendicular magnetic field (not shown) applied to the free layer FL10 from the first conductive line CL10′ and the direction of a non-perpendicular magnetic field (not shown) applied to the free layer FL10 from the second conductive line CL20 may be perpendicular to each other. In this case, the non-perpendicular magnetic fields may be in-plane magnetic fields, and the magnetization of the free layer FL10 may be fluctuated in the horizontal direction by the non-perpendicular magnetic fields.

As depicted in FIGS. 7 and 8, when the multiple conductive lines CL10 and CL20 or CL10′ and CL20 are used, a further increased intensity of a non-perpendicular magnetic field (not shown) may be easily generated. Besides the structures shown in FIGS. 7 and 8, various magnetic memory devices may be realized by mixing at least two magnetic field apply elements of the magnetic field apply elements FA10, FA10′, FA20, and FA30 depicted in FIGS. 1 through 4.

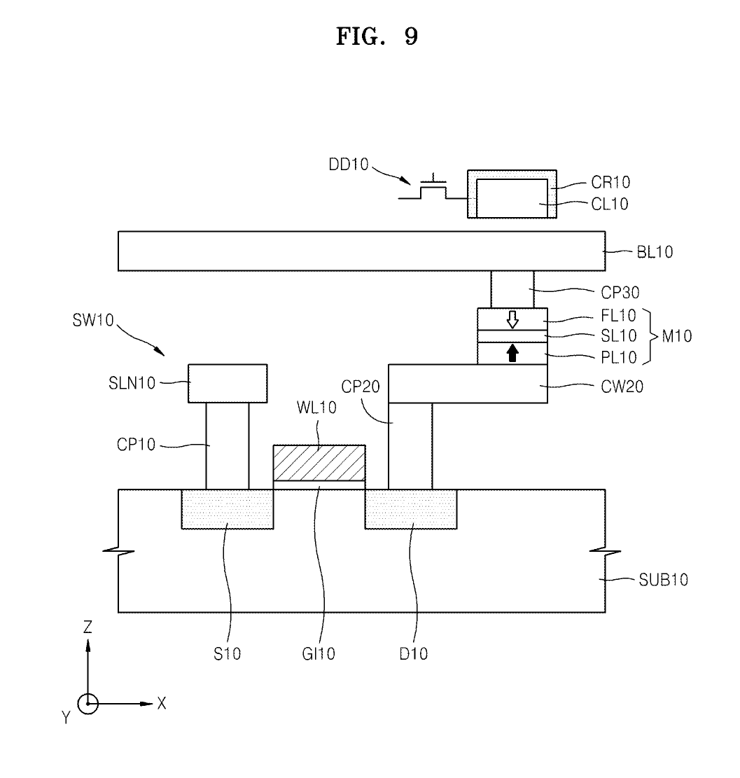

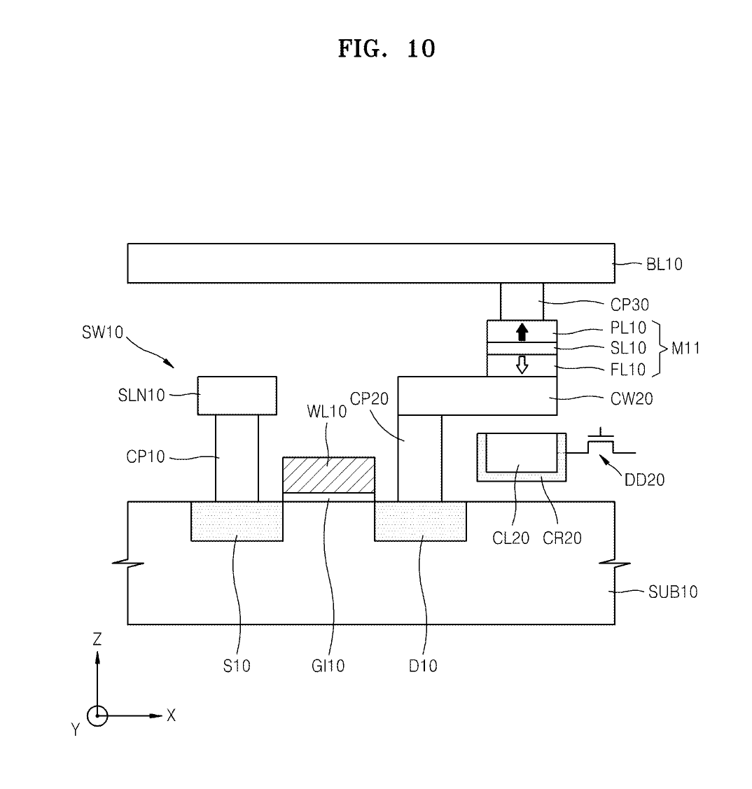

In the example embodiments of FIGS. 1 through 4, 7, and 8, the magnetic memory device 100, 101, 102, 103, 110, and 111 may further include a magnetic field focusing member for focusing the non-perpendicular magnetic fields NF10 through NF30 to the magnetoresistive elements M10 and M11. The examples are shown in FIGS. 9 and 10. The magnetic memory device of FIG. 9 is a modified version of the magnetic memory device of FIG. 1, and the magnetic memory device of FIG. 10 is a modified version of the magnetic memory device of FIG. 3.

Referring to FIG. 9, a cladding layer CR10 that surrounds a portion of the conductive line CL10 may further be included. The cladding layer CR10 may be an example of the magnetic field focusing member. The cladding layer CR10 may have an opening region facing the magnetoresistive elements M10. In other words, the cladding layer CR10 may be provided to cover both side surfaces and an upper surface of the conductive line CL10. A lower surface of the conductive line CL10 facing the magnetoresistive elements M10 may not be covered by the cladding layer CR10. A non-perpendicular magnetic field (for example, an in-plane magnetic field) (not shown) generated from the conductive line CL10 may be focused to the magnetoresistive elements M10 by the cladding layer CR10. The cladding layer CR10 may be formed of a magnetic material that includes at least one selected from the group consisting of Ni, Co, and Fe. For example, the cladding layer CR10 may be formed of a material selected from the group consisting of NiFe, Co, and Fe.

Referring to FIG. 10, a cladding layer CR20 that surrounds a portion of the conductive line CL20 may further be included. The cladding layer CR20 may have an opening region facing the magnetoresistive elements M11. In other words, the cladding layer CR20 may be formed to cover both side surfaces and a lower surface of the conductive line CL20. An upper surface of the conductive line CL20 facing the magnetoresistive elements M11 may not be covered by the cladding layer CR20. A non-perpendicular magnetic field (for example, an in-plane magnetic field) (not shown) generated from the conductive line CL20 may be focused to the magnetoresistive elements M11 by the cladding layer CR20.

Due to the cladding layers CR10 and CR20 of FIGS. 9 and 10, the intensities of the non-perpendicular magnetic fields (NF10 of FIG. 1 and NF20 of FIG. 3) that are applied to the magnetoresistive elements M10 and M11 may be increased. The cladding layers CR10 and CR20 (that is, magnetic field focusing members) of FIGS. 9 and 10 may also be applied to the magnetic memory devices 101, 103, 110, and 111 of FIGS. 2, 4, 7, and 8. In particular, when a cladding layer is applied to the conductive line CL30 of FIG. 4, the cladding layer may be formed on both side surfaces of the conductive line CL30.

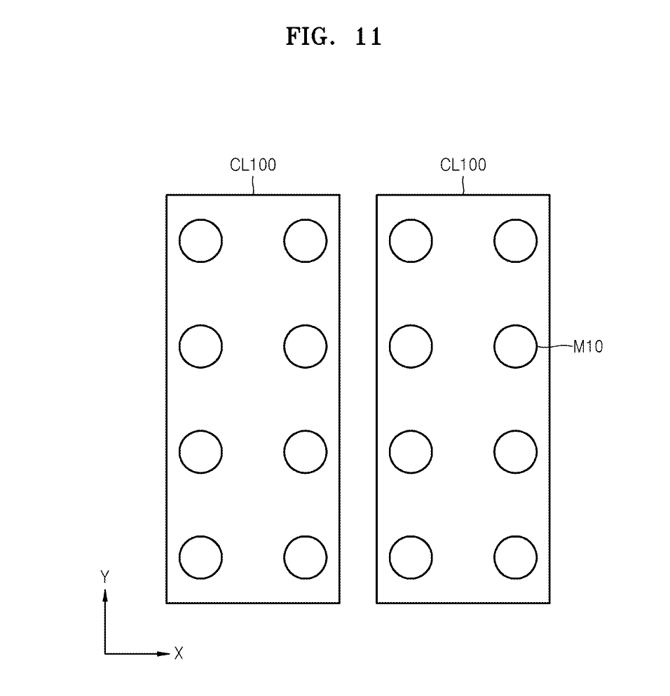

According to example embodiments, a plurality of magnetoresistive elements may be arranged to form a plurality of rows. In this case, a conductive line of a magnetic field apply element may have a width that covers the magnetoresistive elements that form one row of the plurality of magnetoresistive elements. Alternatively, a conductive line of a magnetic field apply element may have width that covers the magnetoresistive elements that form at least two rows of the plurality of magnetoresistive elements. An example of the arrangement is shown in a plan view of FIG. 11.

Referring to FIG. 11, a plurality of magnetoresistive elements M10 may be arranged to form a plurality of rows. The magnetoresistive elements M10 may form a plurality of rows and columns, and may be disposed by separating selected distances. A conductive line CL100 of a magnetic field apply element may have a width that covers the magnetoresistive elements M10 that form at least two rows of the magnetoresistive elements M10. When a conductive line CL100 having a large width is used, because an amount of current that may flows through the conductive line CL100 is increased, a strong magnetic field (that is, a non-perpendicular magnetic field) may be generated from the conductive line CL100. Accordingly, when a conductive line CL100 having a large width is used, a non-perpendicular magnetic field (for example, an in-plane magnetic field) having a strong intensity may be generated. In this regards, the intensity of the non-perpendicular magnetic field may be increased greater than or equal to several hundreds Oersted (Oe). In the current example embodiments, the conductive line CL100 may be disposed above or below the plurality of magnetoresistive elements M10. Also, as depicted in FIG. 11, the conductive line CL100 may extend in the Y-axis direction, but also, may extend in the X-axis direction.

Although not shown in FIG. 11, switching devices respectively connected to the magnetoresistive elements M10 may be included, and a plurality of bit lines extending in the X-axis direction may also be included. The configuration of the switching device and the bit line and the connection of the switching device and the bit line to the magnetoresistive elements M10 may be the same as or similar to the descriptions made with reference to FIGS. 1 through 3.

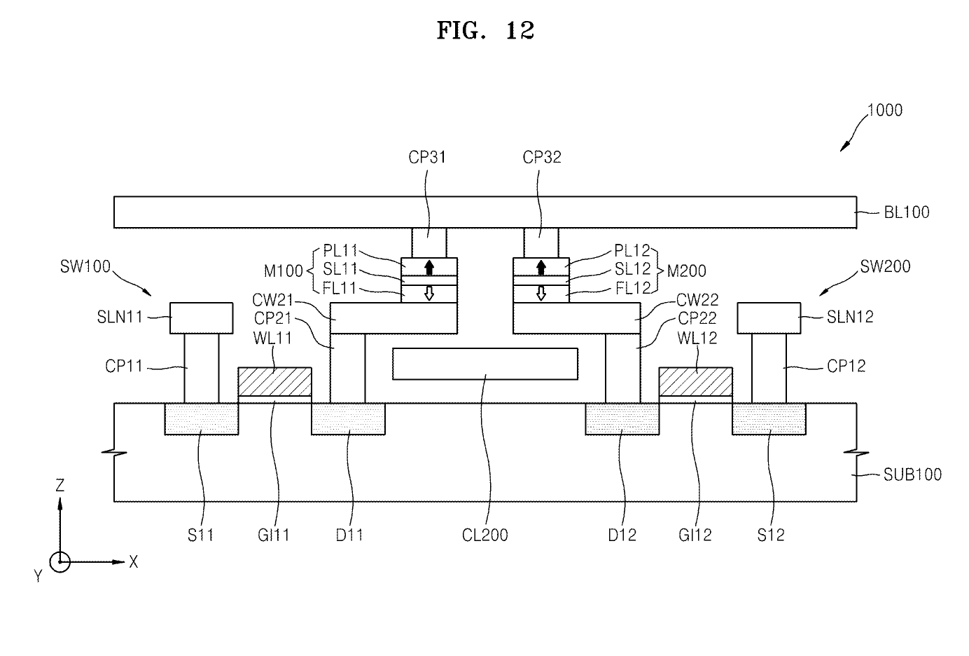

FIG. 12 is a cross-sectional view of a magnetic memory device according to other example embodiments.

In the current example embodiments, another example of using a conductive line having a large width is described.

Referring to FIG. 12, a plurality of magnetoresistive elements, for example, first and second magnetoresistive elements M100 and M200 separated from each other may be provided. Although not shown, a plurality of magnetoresistive elements that form a row identical to the first magnetoresistive element M100 may further be included. Similarly, a plurality of magnetoresistive elements that form a row identical to the second magnetoresistive element M200 may further be included. A first switching device SW100 connected to the first magnetoresistive element M100 may be included, and a second switching device SW200 connected to the second magnetoresistive element M200 may be included.

The first and second switching devices SW100 and SW200 may be formed on a substrate SUB100. The first switching device SW100 may include a first word line WL11, a first source region S11, and a first drain region D11. A first gate insulating layer GI11 may be included between the first word line WL11 and the substrate SUB100. The first source region S11 may be connected to a first source line SLN11 through a first contact plug CP11, and the first drain region D11 may be connected to the first magnetoresistive element M100 through a second contact plug CP21 and a first connection wire CW21. The first magnetoresistive element M100 may be connected to a bit line BL100 through a third contact plug CP31.

The second switching device SW200 may include a second word line WL12, a second source region S12, and a second drain region D12. A second gate insulating layer GI12 may be included between the second word line WL12 and the substrate SUB100. The second source region S12 may be connected to a second source line SLN 12 through a fourth contact plug CP12, and the second drain region D12 may be connected to the second magnetoresistive element M200 through a fifth contact plug CP22 and a second connection wire CW22. The second magnetoresistive element M200 may be connected to the bit line 100 through a sixth contact plug CP32.

The first word line WL11, the first drain region D11, the second drain region D12, and the second word line WL12 may be provided between the first source region S11 and the second source region S12. The first and second magnetoresistive elements M100 and M200 may be disposed between the first switching device SW100 and the second switching device SW200. The first and second magnetoresistive elements M100 and M200 may be disposed between the first drain region D11 and the second drain region D12.

A conductive line CL200 having a width that covers the first and second magnetoresistive elements M100 and M200 may be disposed below the first and second magnetoresistive elements M100 and M200. Because the conductive line CL200 has a large width, a non-perpendicular magnetic field (for example, a horizontal magnetic field) having a strong intensity may be generated from the conductive line CL200.

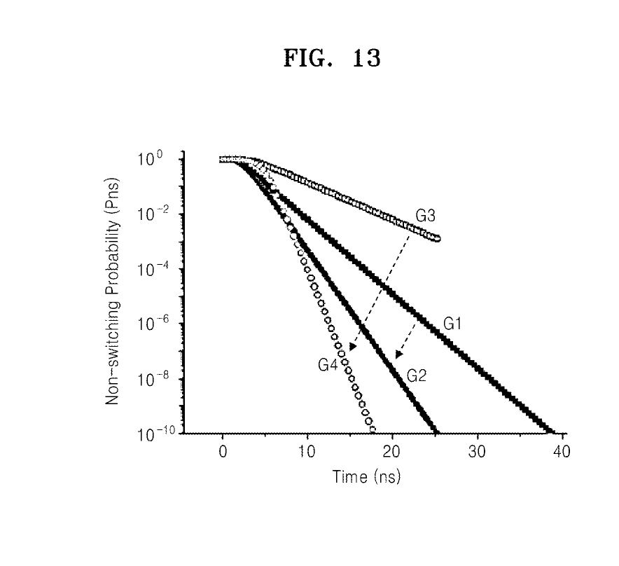

FIG. 13 is a graph showing a non-switching probability (Pns) with respect to switching current applying time in each switching conditions of magnetic memory devices according to example embodiments and a comparative example.

In FIG. 13, first and third graphs G1 and G3 refer to magnetic memory devices according to comparative example, and second and fourth graphs G2 and G4 refer to magnetic memory devices according to example embodiments. The switching conditions of the magnetic memory devices corresponding to the first through fourth graphs G1 through G4 are summarized in Table 1 below.

TABLE 1

| | | Switching | In-plane |
|---|---|---|---|
| | Thickness of | current | magnetic |
| | free layer (nm) | (MA/cm²) | field (Oe) |
| G1 (Comparative example 1) | 2.4 | 20 | — |
| G2 (Embodiment 1) | 2.4 | 20 | 200 |
| G3 (Comparative example 2) | 4.8 | 20 | — |
| G4 (Embodiment 2) | 4.8 | 20 | 200 |

In the magnetic memory devices corresponding to the first and second graphs G1 and G2, a magnetoresistive element, in which a free layer has a thickness of 2.4 nm and has a magnetic anisotropy energy Ku of 1.0×10⁷ erg/cc, is used. In the magnetic memory devices corresponding to the third and fourth graphs G3 and G4, a magnetoresistive element, in which a free layer has a thickness of 4.8 nm and has a magnetic anisotropy energy Ku of 5.1×10⁶ erg/cc, is used. Here, the magnetoresistive elements of the magnetic memory devices corresponding to the first through fourth graphs G1 through G4 have the same thermal stability of approximately 49. The “same thermal stability” denotes that the same data retention characteristic. The magnetoresistive elements of the magnetic memory devices corresponding to the first through fourth graphs G1 through G4 have a width (diameter) of 15 nm and the saturation magnetization Ms of the free layer is 1200 emu/cc.

The magnetic memory devices corresponding to the first and third graphs G1 and G3, according to the comparative example, used a spin transfer torque switching current of 20 MA/cm² for switching the magnetoresistive elements, and did not use a magnetic field (in-plane magnetic field). The magnetic memory devices corresponding to the second and fourth graphs G2 and G4, according to the current example embodiments, used a spin transfer torque switching current of 20 MA/cm² and an in-plane magnetic field of 200 Oersted (Oe) for switching the magnetoresistive elements. Non-switching probabilities Pns with respect to the magnetoresistive elements that include a free layer having the same data retention characteristic (the same thermal stability) have evaluated by varying switching conditions. The non-switching probabilities Pns are evaluated by using Fokker-Planck equation.

Referring to FIG. 13, the second graph G2 is located below the first graph G1 and has an angle of inclination greater than that of the first graph G1. This denotes that the non-switching probability Pns of the magnetic memory device (Embodiment 1) that corresponds to the second graph G2 is smaller than that of the magnetic memory device (Comparative example 1) that corresponds to the first graph G1. In other words, a writing time of the magnetic memory device (Embodiment 1) that corresponds to the second graph G2 is smaller than that of the magnetic memory device (Comparative example 1) that corresponds to the first graph G1. When the same writing time is assumed, a writing current of the magnetic memory device (Embodiment 1) that corresponds to the second graph G2 may be smaller than that of the magnetic memory device (Comparative example 1) that corresponds to the first graph G1. From this result, it is seen that the writing current may be reduced and the writing time may be reduced when writing data by using the spin transfer torque switching current together with the in-plane magnetic field (Embodiment 1) than when writing data by using only the spin transfer torque switching current (Comparative example 1).

Also, the third graph G3 is located above the first graph G1, and has an angle of inclination smaller than that of the first graph G1, and the fourth graph G4 is located below the second graph G2 and has an angle of inclination greater than that of the second graph G2. Accordingly, the difference between the third graph G3 and the fourth graph G4 is greater than the difference between the first graph G1 and the second graph G2. Because the free layers used in the magnetic memory devices that correspond to the third and fourth graphs G3 and G4 have thicknesses greater than the that of the free layers used in the magnetic memory devices that correspond to the first and second graphs G1 and G2, it is seen that the effects (according to the use of an in-plane magnetic field together with the spin transfer torque switching current) according to example embodiments is greater as the thickness of the free layer is increased. In other words, the larger the thickness of the free layer, writing time may further be reduced and writing current may also be further reduced when data are written by using a spin transfer torque switching current together with an in-plane magnetic field. As the thickness of the free layer is increased, thermal stability (that is, data retention time) and MR ratio of a magnetoresistive element may be increased. Also, as the thickness of the free layer is increased, the value of a magnetic anisotropy energy, Kᵤ, of the free layer required for ensuring a data retention characteristic may be reduced. According to example embodiments, writing current and writing time may be significantly reduced, and also, thermal stability and MR ratio may be increased. For these reasons, according to example embodiments, a magnetic memory device having high performance may be realized. That is, a magnetic memory device that has an easiness of writing, a high data retention characteristic, and a high MR ratio may be realized.

In a conventional STT-MRAM, it is not easy to reduce the intensity of a writing current while ensuring a data retention characteristics. Also, it is not easy to increase an MR ratio of an MTJ element while reducing the intensity of a writing current. Accordingly, it is not easy to realize an STT-MRAM that satisfies a writing easiness, a high data retention characteristic, and a high MR ratio. However, according to the example embodiments, as described above, a magnetic memory device that has a high thermal stability (high data retention characteristic) and a high MR ratio while ensuring a writing easiness.

While the disclosure has been particularly shown and described with reference to example embodiments thereof, it should not be construed as being limited to the embodiments set forth herein but as an exemplary. It will be understood by those of ordinary skill in the art that the structures of the magnetic memory devices of FIGS. 1 through 4 and FIGS. 7 through 12 may be modified in various ways. As practical examples, the magnetoresistive elements M10, M11, M100, and M200 may further include at least one layer besides the pinned layers PL10, PL11, and PL12, the separation layers SL10, SL11, and SL12, and the free layers FL10, FL11, and FL12. Also, it will be understood that the structures of the switching devices SW10, SW100, and SW200 and the structures of the magnetic field apply elements FA10, FA10′, FA20, and FA30 may be modified in various ways. Also, it will be understood that the operation method described with reference to FIGS. 5A through 5F may be modified in various ways. Therefore, the scope is defined not by the detailed description but by the appended claims.

What is claimed is:

1. A magnetic memory device, comprising:
a magnetoresistive element including a free layer and a pinned layer, wherein the free layer and the pinned layer each have a perpendicular magnetic anisotropy;
a current apply element configured to apply a spin transfer torque switching current to the magnetoresistive element; and
a magnetic field apply element configured to apply a non-perpendicular magnetic field to the magnetoresistive element,
wherein the magnetic memory device is configured to write data in the magnetoresistive element by using the spin transfer torque switching current and the non-perpendicular magnetic field.

2. The magnetic memory device of claim 1, wherein the non-perpendicular magnetic field includes an in-plane magnetic field.

3. The magnetic memory device of claim 1, wherein the magnetic field apply element includes at least one conductive line spaced apart from the magnetoresistive element.

4. The magnetic memory device of claim 3, wherein,
the conductive line is above the magnetoresistive element, and
the magnetoresistive element has a bottom-pinned type structure in which the pinned layer is below the free layer.

5. The magnetic memory device of claim 3, wherein,
the conductive line is below the magnetoresistive element, and
the magnetoresistive element has a top-pinned type structure in which the pinned layer is above the free layer.

6. The magnetic memory device of claim 1, wherein,
the current apply element includes a switching device and a bit line,
the switching device is connected to a first region of the magnetoresistive element and includes a word line, and
the bit line is connected to a second region of the magnetoresistive element.

7. The magnetic memory device of claim 6, wherein the magnetic field apply element includes a first conductive line above the bit line, and
wherein the first conductive line extends in a direction parallel to the word line or in a direction perpendicular to the word line.

8. The magnetic memory device of claim 6, wherein,
the magnetic field apply element includes a second conductive line below the magnetoresistive element,
the magnetoresistive element is between the bit line and the second conductive line, and
the second conductive line extends in a direction parallel to the word line.

9. The magnetic memory device of claim 6, wherein the word line is the magnetic field apply element, and
wherein the magnetoresistive element is above the word line.

10. The magnetic memory device of claim 1, wherein the magnetic field apply element includes a first conductive line above the magnetoresistive element and a second conductive line below the magnetoresistive element.

11. The magnetic memory device of claim 1, further comprising:
a magnetic field focusing member configured to focus the non-perpendicular magnetic field towards the magnetoresistive element.

12. The magnetic memory device of claim 11, wherein,
the magnetic field focusing member includes a cladding layer surrounding a portion of the magnetic field apply element, and
the cladding layer includes an opening region facing the magnetoresistive element.

13. The magnetic memory device of claim 1, further comprising a plurality of magnetoresistive elements collectively arranged in a plurality of rows.

14. The magnetic memory device of claim 13, wherein,
the magnetic field apply element includes at least one conductive line, and
the conductive line has a width that covers a first group from among the plurality of magnetoresistive elements, the first group being collectively arranged in at least two rows from among the plurality of rows.

15. The magnetic memory device of claim 14, wherein,
the plurality of magnetoresistive elements each include a first magnetoresistive element and a second magnetoresistive element,
the current apply element include a first switching device and a second switching device respectively connected to the first and second magnetoresistive elements,
the first and second magnetoresistive elements are between the first switching device and the second switching device, and
the conductive line is below the first and second magnetoresistive elements and has a width that covers the first and second magnetoresistive elements.

16. The magnetic memory device of claim 1, wherein the magnetic field apply element is configured to start applying the non-perpendicular magnetic field to the magnetoresistive element before or simultaneously with the application of the spin transfer torque switching current to the magnetoresistive element.

17. A method of operating a magnetic memory device including a magnetoresistive element, the magnetoresistive element including a free layer and a pinned layer each having a perpendicular magnetic anisotropy, the method comprising:
writing data in the magnetoresistive element by,
applying a non-perpendicular magnetic field to the magnetoresistive element, and
applying a spin transfer torque switching current to the magnetoresistive element while applying the non-perpendicular magnetic field to the magnetoresistive element.

18. The method of claim 17, wherein the non-perpendicular magnetic field includes an in-plane magnetic field.

19. The method of claim 17, wherein the applying of the non-perpendicular magnetic field to the magnetoresistive element is started before or simultaneously with the applying of the spin transfer torque switching current.

20. The method of claim 19, wherein the applying of the non-perpendicular magnetic field is started in an amount of time ranging from about 0 ns to about 20 ns before the applying of the spin transfer torque switching current.
